(19) United States
(12) Patent Application Publication
(10) Pub. No.: US 2018/0356455 A1
(43) Pub. Date: Dec. 13, 2018

(54) CAPACITANCE SENSOR

(71) Applicant: David Rice, Port Washington, WI (US)

(72) Inventor: David Rice, Port Washington, WI (US)

(21) Appl. No.: 15/621,829

(22) Filed: Jun. 13, 2017

(51) Int. Cl. G01R 31/12; G01R 23/09; H03B 5/22; H01G 4/018; H01G 11/82; G06F 9/24; G01F 23/26

(52) U.S. Cl. CPC G01R 31/1245; G01R 23/09; H03B 5/22; H01G 4/018; G01F 23/268; G06F 9/24; G01F 23/265; G01F 23/266; H01G 11/82

(57) ABSTRACT

A capacitance sensor includes flexible interdigitated electrodes and an uncomplicated, compact control circuit including a frequency meter, a resistance capacitance oscillator, a display, and a microcontroller to manage these components. In an exemplary method of use of the capacitance sensor to monitor known parameters of a fluid, the flexible electrodes may be inserted into a circular tubular conduit containing the fluid. As fluid flows past the electrodes, any discrepancies from the known parameters may be detected and signaled immediately.

### FIELD OF THE DISCLOSURE

The present disclosure relates to capacitance sensors and in an exemplary use, to determine anomalies in fluids.

### BACKGROUND

Fluids such as water must be monitored for contamination from time to time. In an example, pure water may be monitored for contamination by any foreign substance. In some situations, it is desirable to report results instantly. For example, dialysis solutions must be monitored to prevent infections and other ill effects to patients. In industrial settings requiring ultra pure water, such as semiconductor manufacture, any contamination must be detected to prevent compromised semiconductor products. Pharmaceuticals must be monitored to assure requisite purity and sterility. Food and beverage preparation require detection of potential contamination by hazardous bacteria such as Listeria and E. coli.

Instrumentation has been provided for detecting contaminants Mere presence of a contaminant may be the object of monitoring. Alternatively, levels of a contaminant may require monitoring or the level of contamination must be known if it reaches a predetermined threshold.

Many types of sensors can respond to specific contaminants, or to levels of contaminants and concentrations of desired substances, but may not be able to detect all contaminant or concentration based anomalies which would establish an alarm condition.

There exists a need for a sensor which can instantly detect contaminants or alternatively, unacceptable levels of contaminants and otherwise desired substances in a fluid. It is further desirable to provide a universal sensor which can detect many different contaminants and levels of substances and report the same expeditiously. It is still further desirable that such a universal sensor be non-invasive relative to a system being monitored.

### SUMMARY

The disclosed concepts address the above stated situation by providing a sensor which responds to contaminants and undesirable concentrations of substances in a fluid. The disclosed sensor and related methods enable instantaneous detection and reporting. The disclosed sensor and related methods enable non-invasive monitoring of fluid conduits and containers.

To these ends, there is provided a capacitance sensor capable of being placed in contact with a monitored fluid. The sensor includes a flexible, interdigitated array of electrodes, with a minimally complex electronic control circuit located nearby. The control circuit may include a frequency meter, a resistance capacitance oscillator, a display, and a microcontroller to manage these components.

The flexible array of electrodes enables the electrodes to be placed advantageously within a tubular conduit, or otherwise in intimate contact with fluids being monitored.

The novel capacitance sensor can be used to monitor any departure from a predetermined capacitance value/contamination level, and signal such departure immediately. This is useful for example in any system using pure water, such as in medical applications, contamination sensitive manufacturing, and others. Upon receipt of an alarm signal indicating departure from the predetermined capacitance value, corrective measures may be employed with minimal response time.

Application of the novel capacitance sensor need not be limited to a pure fluid. For example, in sewage treatment, the fluid may be contain contaminants in known concentrations. Such a condition would be indicative of the system operating as intended. However, any discrepancy from the known concentrations could trigger an alarm signal, with corrective actions being initiated before consequences of the discrepancy could cause significant damage to system operation.

It is an object to provide improved elements and arrangements thereof by apparatus for the purposes described which is inexpensive, dependable, and fully effective in accomplishing its intended purposes.

These and other objects will become readily apparent upon further review of the following specification and drawings.

### BRIEF DESCRIPTION OF THE DRAWINGS

Various objects, features, and attendant advantages of the disclosed concepts will become more fully appreciated as the same becomes better understood when considered in conjunction with the accompanying drawings, in which like reference characters designate the same or similar parts throughout the several views, and wherein:

FIG. 1 is an environmental perspective view of a capacitance sensor, according to at least one aspect of the disclosure;

FIG. 2 is a cross sectional detail view of an electrode array of the capacitance sensor of FIG. 1, taken along line 2-2 in FIG. 1, and is drawn to enlarged scale;

FIG. 3 is a graphical representation of major components of a control circuit of the capacitance sensor of FIG. 1;

FIG. 4 is a top plan detail view of an electrode array of the capacitance sensor of FIG. 1, according to at least one aspect of the disclosure;

FIG. 5 is a top plan view of an electrode array of the capacitance sensor of FIG. 1, according to at least one further aspect of the disclosure;

FIG. 6 is a perspective view of a capacitance sensor, according to at least one aspect of the disclosure; and

FIG. 7 is an electrical schematic showing exemplary connections of the control circuit of the novel capacitance sensor, according to at least one aspect of the disclosure.

### DETAILED DESCRIPTION

In the following description, numerous specific details are set forth in order to provide an understanding of the present invention. It will be apparent, however, to one skilled in the art that the present invention may be practiced without these specific details. In other instances, well known components or methods have not been described in detail but rather in a block diagram in order to avoid unnecessarily obscuring the present invention. Thus, the specific details set forth are merely exemplary. The specific details may be varied from and still be contemplated to be within the spirit and scope of the present invention.

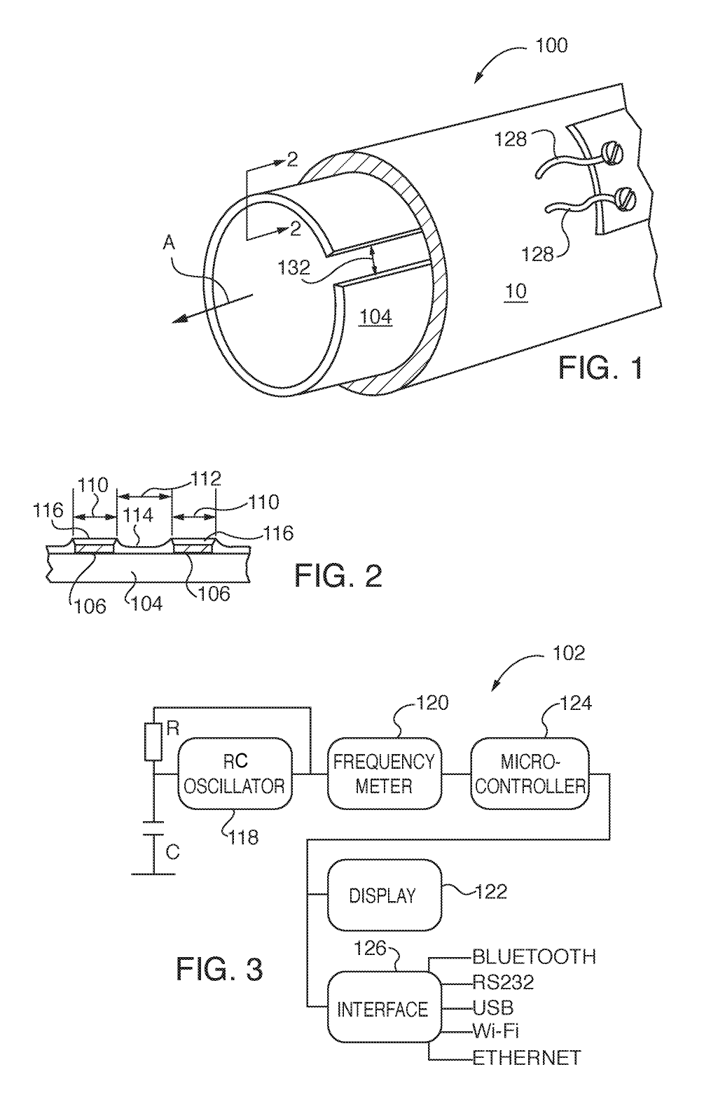

Referring first to FIGS. 1-3, according to at least one aspect of the disclosure, there is shown a capacitance sensor 100 for sensing contaminants (not shown) and undesired concentrations of substances (not shown) in a fluid being monitored and contained within a vessel 10. In FIG. 1, a sensing portion of capacitance sensor 100 is shown rolled into a cylindrical configuration for insertion into and occupancy of the interior of vessel 10, with control components or control circuit 102 installed externally to vessel 10. Capacitance sensor 100 may comprise a flexible substrate 104 bearing two electrodes 106 spaced apart from one another by gaps 108 (see Fig.). No 108 Each of electrodes 106 has a width 110 in plan view, and each of gaps 108 no 108 has a width 112 in plan view similar in magnitude than width 110 of electrodes 106. A dielectric material 114 is between electrodes 106. Electrical insulation 116 covers electrodes 106.

Control circuit 102 comprises a source of electrical input signals (e.g., RC (Resistance-Capacitor) (oscillator 118) connected to electrodes 106, a frequency meter 120 in frequency sensing relation to the two electrodes, a display 122 for annunciating capacitance values, and a microcontroller 124 arranged to process capacitance signals from frequency meter 120 and to generate responsively signals indicative of determined capacitance values from the capacitance signals. Resistance capacitance oscillator 118 may be arranged to establish a predetermined frequency of the electrical input signals. The source of electrical input signals may comprise frequency meter 120 arranged to sense frequency of capacitance output signals from electrodes 106. Control circuit 102 may further comprise a communications interface 126 capable of transmitting communications signals indicative of the capacitance output signals to a remote data handling device (not shown). Data interface 126 may be connected to microcontroller 124 and configured to transmit data corresponding to the signals indicative of determined capacitance values from microcontroller 124 to the remote data handling device using at least one of Bluetooth, an RS232 standard, a universal serial bus (USB), Wi-Fi, or Ethernet or any other communication system. An exemplary partial layout of control circuit 102 is shown in FIG. 7. In the circuit, a temperature sensor U3 and R4 is used to measure the temperature of the fluid to improve the accuracy of the sensor as it will allow it to compensate for the temperature dependency of some contaminants.

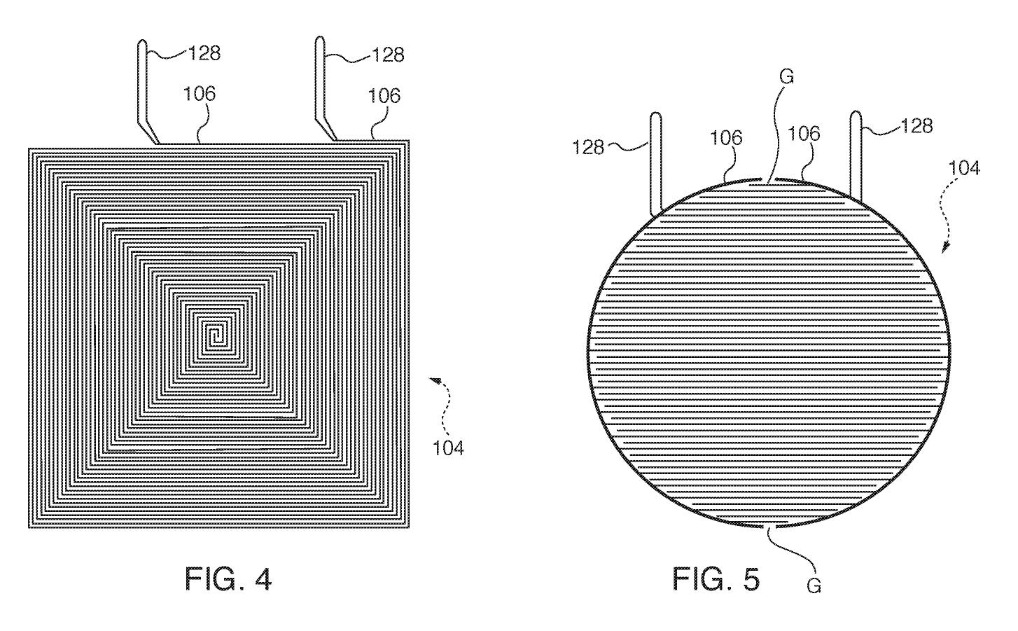

Also referring now to FIGS. 4 and 5, electrodes 106 each comprise an array of members interdigitated with members of the other electrode 106. Electrodes 106 may each comprise a flexible metal trace. Electrical insulating material 116 on electrodes 106 may comprise epoxy or sputtered glass. Alternatively, other materials, such as silicone, may be employed for electrical insulating material 116 or for dielectric material 114, where flexibility is required. A degree of flexibility will be desired where flexible substrate 104 is to be rolled or coiled for insertion into a cylindrical vessel such as vessel 10 shown in FIG. 1. In FIGS. 4 and 5, electrodes 106 are provided with shielded conductors or wires 128 to enable connection between electrodes 106 and control circuit 102.

Flexible substrate 104 bearing the two electrodes may be rectangular in plan view when laid on a flat surface (FIG. 4) or alternatively, may be circular in plan view when laid on a flat surface (FIG. 5). If desired, flexible substrate 104 and hence the array of electrodes 106 may take on other configurations if desired.

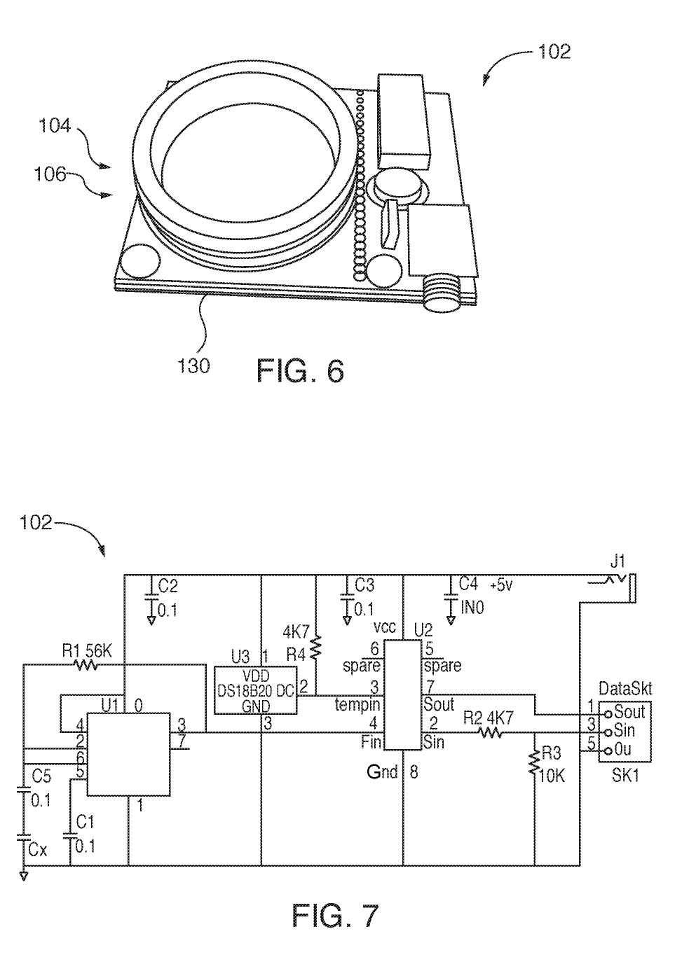

Turning now to FIG. 6, flexible substrate 104 and control circuit 102 may be mounted proximate one another on a planar supporting substrate 130. This arrangement may be employed for example to monitor or assess small samples of fluids.

It will be appreciated that control circuit 102 and flexible substrate 104 and its electrodes 106 may be compactly realized if mounted on a single substrate such as planar supporting substrate 130. In alternative constructions, any of RC oscillator 118, frequency meter 120, display 122, microcontroller 124, and interface 126 may be located remotely from others of these listed components, and may be connected by hard wiring.

Capacitance sensor 100 may be utilized in a method of rapidly determining an unacceptable parameter of water within a vessel (e.g., vessel 10) having an internal configuration. As employed herein, rapidly means within a one second time interval. The method may comprise the steps of establishing a predetermined capacitance value for pure water, using capacitance sensor 100 having flexible substrate 104 bearing interdigitated electrodes 106, forming flexible substrate 104 and interdigitated electrodes 106 into a configuration complementing that of the vessel and inserting flexible substrate 104 and interdigitated electrodes 106 into the vessel in contact with internal surfaces of the vessel, and monitoring capacitance of fluid flowing in the vessel for a discrepancy from the predetermined capacitance value of pure water. The method may further comprise issuing a signal immediately, responsive to detecting the discrepancy from the predetermined capacitance value of pure water.

In this method, when the vessel comprises a cylindrical annular tube, the step of forming flexible substrate 104 and interdigitated electrodes 106 into a configuration complementing that of the vessel comprises forming flexible substrate 104 and interdigitated electrodes 106 into a generally cylindrical configuration of dimensions just less than those of the cylindrical annular tube. The term “generally cylindrical” signifies that the outside and inside surfaces of flexible substrate 104 take on the contour of a cylinder, but do not necessarily complete the cylindrical shape. For example, and referring specifically to FIG. 1, flexible substrate 104 forms less than a full cylinder due to existence of gap 132. Flexible substrate 104 and hence electrodes 106 will approximate the cylindrical interior surface of vessel 10, and hence will be sufficiently in intimate contact with fluid flowing (e.g., in the direction of arrow A) within vessel 10 as to be able to successfully discern discrepancies from the predetermined capacitance of pure water or any other fluid contained within vessel 10.

It will be noted in FIG. 1 that flexible substrate 104 and electrodes 106 are within vessel 10, while control circuit 102 is conveniently mounted at the exterior of vessel 10. In such cases, electrodes 106 are connected to control circuit 102 by wires 128, the latter penetrating vessel 10.

Symbols used in the various drawing Figures, if not explicitly described herein, retain their conventional meanings as used in the field of electrical circuit graphics used for general purpose industrial practice.

In this application, characteristics are recited with the understanding that prevailing conditions are those of ordinary use of the described subject matter. Therefore, although characteristics could change given circumstances other than the ordinary intended usage of the novel apparatus or method, such changes are to be ignored.

While the disclosed concepts have been described in connection with what is considered the most practical and preferred implementation, it is to be understood that the disclosed concepts are not to be limited to the disclosed arrangements, but are intended to cover various arrangements which are included within the spirit and scope of the broadest possible interpretation of the appended claims so as to encompass all modifications and equivalent arrangements which are possible.

I claim:

1. A capacitance sensor for sensing contaminants and undesired concentrations of substances in a fluid being monitored and contained within a vessel, the capacitance sensor comprising:
a flexible substrate bearing
two electrodes spaced apart from one another by gaps, wherein each of the electrodes has a width in plan view, and each of the gaps has a width in plan view greater in magnitude than the width of the electrodes,
dielectric material between the two electrodes, and
electrical insulation covering the two electrodes; and
a control circuit comprising:
a source of electrical input signals connected to the two electrodes;
a frequency meter in frequency sensing relation to the two electrodes;
a display for annunciating capacitance values; and
a microcontroller arranged to process capacitance signals from the frequency meter and to generate responsively signals indicative of determined capacitance values from the capacitance signals.

2. The capacitance sensor of claim 1, wherein the two electrodes each comprise an array of members interdigitated with members of the other electrode.

3. The capacitance sensor of claim 1, wherein the source of electrical input signals comprises a resistance capacitance oscillator arranged to establish a predetermined frequency of the electrical input signals.

4. The capacitance sensor of claim 1, wherein the source of electrical input signals comprises a frequency meter arranged to sense frequency of capacitance output signals from the two electrodes.

5. The capacitance sensor of claim 1, further comprising a communications interface capable of transmitting communications signals indicative of the capacitance output signals to a remote data handling device.

6. The capacitance sensor of claim 1, wherein the two electrodes each comprise a flexible metal trace, and the electrical insulation on the electrodes comprises epoxy.

7. The capacitance sensor of claim 1, wherein the two electrodes each comprise a flexible metal trance trace, and the electrical insulation on the electrodes comprises sputtered glass.

8. The capacitance sensor of claim 1, further comprising a data interface connected to the microcontroller and configured to transmit data corresponding to the signals indicative of determined capacitance values from the microcontroller to a remote data handling device using at least one of Bluetooth, an RS232 standard, a universal serial bus (USB), Wi-Fi, or Ethernet.

9. The capacitance sensor of claim 1, wherein the flexible substrate bearing the two electrodes is rectangular in plan view when laid on a flat surface.

10. The capacitance sensor of claim 1, wherein the flexible substrate bearing the two electrodes is circular in plan view when laid on a flat surface.

11. The capacitance sensor of claim 1, wherein the flexible substrate and the control circuit are mounted proximate one another on a planar supporting substrate.

12. A method of rapidly determining an unacceptable parameter of water within a vessel having an internal configuration, the method comprising the steps of:
establishing a predetermined capacitance value for pure water;
using a capacitance sensor having a flexible substrate bearing two interdigitated electrodes, forming the flexible substrate and interdigitated electrodes into a configuration complementing that of the vessel and inserting the flexible substrate and interdigitated electrodes into the vessel in contact with internal surfaces of the vessel; and
monitoring capacitance of fluid flowing in the annular fluid conduit for a discrepancy from the predetermined capacitance value of pure water; and
issuing a signal immediately, responsive to detecting the discrepancy from the predetermined capacitance value of pure water.

13. The method of claim 12, wherein, when the vessel comprises a cylindrical annular tube, the step of forming the flexible substrate and interdigitated electrodes into a configuration complementing that of the vessel comprises forming the flexible substrate and interdigitated electrodes into a generally cylindrical configuration of dimensions just less than those of the cylindrical annular tube.
